(19) United States
(12) Patent Application Publication
(10) Pub. No.: US 2022/0403507 A1
(43) Pub. Date: Dec. 22, 2022

(54) SUSCEPTOR CLEANING

(71) Applicant: ASM IP Holding B.V., Almere (NL)

(72) Inventor: Ivo Raaijmakers, Almere (NL)

(21) Appl. No.: 17/840,870

(22) Filed: Jun. 15, 2022

Related U.S. Application Data
(60) Provisional application No. 63/212,313, filed on Jun. 18, 2021.

(51) Int. Cl. C23C 16/44; H01L 21/687; H01J 37/32; C23C 16/50

(52) U.S. Cl. CPC C23C 16/4405; H01L 21/68707; H01J 37/32899; H01J 37/32733; C23C 16/50; H01J 2237/335

(57) ABSTRACT

The current disclosure relates to a vapor deposition assembly for depositing material on a substrate. The vapor deposition assembly comprises a treatment chamber for treating susceptors from a deposition chamber that comprises multiple, moveable susceptors. The assembly further comprises a transfer system configured and arranged to move a susceptor between the deposition chamber and the treatment chamber. The disclosure further relates to a method of cleaning as susceptor and to a susceptor treatment apparatus.

### CROSS-REFERENCE TO RELATED APPLICATIONS

This application claims priority to U.S. Provisional Patent Application Ser. No. 63/212,313 filed Jun. 18, 2021 titled SUSCEPTOR CLEANING, the disclosure of which is hereby incorporated by reference in its entirety.

### FIELD

The present disclosure relates to methods and apparatuses for the manufacture of semiconductor devices. More particularly, the disclosure relates to vapor deposition assemblies, and susceptor cleaning systems therein.

### BACKGROUND

During semiconductor device manufacture, various material layers are sequentially deposited onto semiconductor substrates. This takes place in a carefully controlled environment in deposition chambers, where a substrate may be placed on a susceptor for holding it during a deposition process. As a vapor deposition apparatus must be able to perform the deposition with utmost precision and repeatability, only a limited number of deposition steps, typically only one, may be performed in a single deposition chamber. The need to transfer the substrate from one deposition chamber to another negatively affects the throughput of device manufacturing.

So-called multi-station chambers are being developed to speed up sequential deposition of materials that are incompatible to be deposited in one space. In such chambers, a substrate is placed on a susceptor, and the susceptor is moved from one deposition station to another inside the chamber. As the susceptor is repeatedly exposed to different deposition steps, the deposited material will accumulate on it, which may decrease the susceptor performance. However, cleaning the susceptor will result in downtime of at least one deposition station. Therefore, there is need in the art for methods and apparatuses for cleaning a susceptor while maintaining the efficiency benefits gained by multi-station chamber design.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

In an aspect, a vapor deposition assembly for depositing material on a substrate is disclosed. The vapor deposition assembly comprises a deposition chamber comprising at least two deposition stations for depositing a material on a substrate, a plurality of susceptors each configured and arranged to hold a substrate, a susceptor moving arrangement configured and arranged to detachably hold a susceptor and to move said susceptor between deposition stations, a treatment chamber constructed and arranged to receive and treat a susceptor from the deposition chamber, and a transfer system configured and arranged to move the susceptors between the deposition chamber and the treatment chamber.

In some embodiments, the deposition assembly comprises a second transfer system configured and arranged to move a susceptor inside the treatment chamber.

In some embodiments, the susceptor moving arrangement is configured and arranged to move all the susceptors simultaneously.

In some embodiments, the susceptor moving arrangement rotates the susceptors in a circular manner about a rotational axis in between the susceptors.

In some embodiments, the assembly further comprises a susceptor staging station for holding one or more treated susceptors.

In some embodiments, the susceptor staging station is positioned in the deposition chamber.

In some embodiments, the assembly comprises more susceptors than deposition stations.

In some embodiments, the treatment chamber is a cleaning chamber.

In some embodiments, the cleaning chamber is a plasma cleaning chamber, a thermal cleaning chamber, an etch cleaning chamber, a chemical cleaning chamber, radiation cleaning chamber, an annealing chamber, a sputter cleaning chamber or a combination thereof.

In some embodiments, the treatment chamber is configured and arranged to treat a susceptor.

In some embodiments, the treatment chamber is configured and arranged to treat a substrate and a susceptor.

In some embodiments, the treatment chamber is configured and arranged to condition a susceptor.

In some embodiments, the conditioning comprises coating a susceptor.

In some embodiments the conditioning comprises annealing a susceptor.

In some embodiments, the deposition assembly comprises a substrate-handling system, and the substrate-handling system is configured and arranged to be used as the susceptor transfer system.

In some embodiments, the treatment chamber is configured and arranged to receive susceptors from at least two deposition chambers.

In an aspect, a treatment apparatus for treating susceptors of a vapor deposition assembly is disclosed. In some embodiments, the apparatus comprises a housing, a susceptor holder configured and arranged to hold a susceptor to be treated, a treatment arrangement configured and arranged to treat a susceptor, wherein the susceptor treatment apparatus is configured and arranged to receive a susceptor from at least two deposition chambers.

In some embodiments, the treatment apparatus comprises transfer system for moving susceptor between the susceptor holder and a deposition chamber.

In some embodiments, the treatment apparatus comprises a susceptor staging station for storing susceptors.

In another aspect, a method of cleaning a substrate is disclosed. The method comprises removing a susceptor from a susceptor moving arrangement in a vapor deposition chamber comprising at least two deposition stations, inserting the susceptor in a susceptor cleaning chamber connected to the vapor deposition chamber and cleaning the susceptor.

In some embodiments, cleaning comprises providing a plasma in the susceptor cleaning chamber and/or heating the susceptor cleaning chamber.

In some embodiments, cleaning comprises providing an etchant in the susceptor cleaning chamber.

In some embodiments, cleaning comprises cleaning nitride material from the susceptor.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings.

FIG. 1 is a schematic overview of a deposition assembly according to the current disclosure as a top view.

FIG. 2 depicts an embodiment of a deposition chamber and a treatment chamber according to the current disclosure as a top view.

FIG. 3 presents an embodiment of a treatment apparatus according to the current disclosure as a schematic top view.

FIG. 4 depicts an embodiment of a deposition chamber and a treatment chamber according to the current disclosure as a top view.

FIG. 5 presents the embodiment of FIG. 4 as a schematic side view.

FIG. 6 is a flow diagram presenting an embodiment of a method according to the current disclosure.

### DETAILED DESCRIPTION

The description of exemplary embodiments of apparatuses and methods provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The current disclosure relates to vapor deposition assemblies for depositing material on a substrate. More specifically, the current disclosure relates to deposition assemblies that have at least one deposition chamber comprising more than one deposition station. A substrate, such as a semiconductor substrate, may be mounted on a susceptor that moves between deposition stations. The deposition stations are isolated from each other to an extent that allows different deposition processes to be performed in each deposition station. In other words, deposition conditions in each deposition station may be at least partially independently adjusted. The deposition stations may be physically sealed compartments during substrate processing. Alternatively, the gas atmospheres of the deposition stations may be separated by gas curtains or other means preventing mixing the possibly different gases of deposition stations. Each deposition station may comprise the necessary components to perform a specific processing step or steps. Further, a deposition assembly according to the current disclosure comprises suitable software to run each deposition station as desired, and suitably coordinated with other deposition stations.

As is known to those skilled in the art of semiconductor processing, a multi-step deposition process may comprise steps that remove or modify material from the substrate. For example, deposition may be area-selective, and obtaining sufficient selectivity may require occasional etch-back steps to be performed in addition to depositing material on the substrate. Additionally, some process steps, also encompassed by the term deposition as used herein, may chemically comprise modification reactions. For example, a metal oxide surface may be reduced into an elemental metal, or the properties of a deposited material may be altered through thermal treatment. Thus, all the various processing steps that may be needed to obtain a functional semiconductor device or an integrated circuit are encompassed by the term deposition as used herein. However, any single deposition assembly does not necessarily perform all the possible processing steps. Typically, a subset of a certain types of processes, or a series of processes leading to a pre-determined structure are performed in a single deposition assembly.

A deposition chamber according to the current disclosure may comprises at least one deposition station in which material is deposited on the surface of a susceptor. Many treatments preformed in a deposition station may lead to the change of susceptor surface properties, most notably the accumulation of deposited material on the susceptor. As a single susceptor may be holding a substrate through multiple deposition and/or treatment steps, the changes in the susceptor surface may begin to affect the deposition processes. In addition to the accumulation of deposited material, also changes in the surface properties of the susceptor itself may result in process drift in the deposition chamber, for example.

A deposition assembly according to the current disclosure may be a cluster tool in which different processes are performed to form an integrated circuit. A deposition assembly according to the current disclosure may be a part of a cluster tool. In some embodiments, at least one of the deposition stations may be a showerhead station. A showerhead station comprises a showerhead for providing a reactant into the reaction station.

A deposition chamber according to the current disclosure comprises at least two deposition stations for depositing a material on a substrate. Thus, a deposition chamber may comprise more than one deposition station. For example, a deposition chamber may comprise two, three, four, five, six, seven or more deposition stations. In some embodiments, deposition chamber comprises at least three deposition stations. In some embodiments, a deposition chamber comprises at least four deposition stations. In some embodiments, a deposition chamber comprises at least five deposition stations. In some embodiments, a deposition chamber comprises at least six deposition stations. A deposition station may comprise gas inlets, gas outlets, temperature regulation systems and other components used in a deposition process.

A deposition chamber further comprises a plurality of susceptors configured and arranged to hold a substrate. A susceptor according to the current disclosure may comprise an electric chuck to hold a substrate on the susceptor. A susceptor may comprise additional components known in the art, as a heating system, lift pins, gas channels, electrostatic chucking/dechucking and the like. In some embodiments, one susceptor holding one substrate, for example a silicon wafer, is processed in a deposition station at a time. A susceptor according to the current disclosure may be removeable so that it may be transferred to a treatment chamber for cleaning or other treatment to retain or restore its functionality. Thus, the susceptor and/or a susceptor stand may be configured and arranged to function separably. A susceptor may be supported by a susceptor stand that may be a component of a susceptor moving arrangement. In some embodiments, a susceptor may be detachably attached to a susceptor stand.

### Susceptor Moving Arrangement

A susceptor moving arrangement is configured and arranged to detachably hold a susceptor and to move said susceptor between deposition stations. The susceptor moving arrangement may be designed in various ways. In some embodiments, it may be beneficial for the susceptor moving arrangement to move all the susceptors simultaneously. This may reduce the time needed for moving susceptors—and substrates thereon—between deposition stations compared to, for example, embodiments in which robot arms move individual susceptors. Moving susceptors simultaneously may be advantageous, for example, in applications where each of the processes or series of processes performed in the deposition stations are approximately of the same length. If, however, processes or series of processes performed in the deposition stations have differing durations, it may be possible to allocate a different number of deposition stations to different processes. For example, in such embodiments a susceptor moving arrangement capable of moving individual susceptors between deposition stations may be advantageous.

In some embodiments, the susceptor moving arrangement is shaped to form a sealed space when positioned at a deposition station. For example, a susceptor stand to which a susceptor is attached may form a portion of a deposition station structures that enclose the space in which the deposition processes are performed.

In some embodiments, a susceptor moving arrangement rotates the susceptors in a circular manner about a rotational axis situated in between the susceptors. The rotational axis may extend perpendicularly to the plane of the substrate surfaces to be processed. In some embodiments, the rotational axis may be vertical, and the susceptors holding the substrates may move horizontally in a circular manner.

### Treatment Chamber

The deposition assembly according to the current disclosure comprises a treatment chamber. A treatment chamber is constructed and arranged to receive and treat a susceptor from the deposition chamber. The purpose of the treatment may be to clean a susceptor from accumulated deposited material. Thus, in some embodiments, the treatment chamber is a cleaning chamber. Methods of cleaning a susceptor include plasma cleaning, thermal cleaning, cleaning by etchant, chemical cleaning or a radiation cleaning. In some embodiments, a cleaning chamber is a plasma cleaning chamber, a thermal cleaning chamber, an etch cleaning chamber, a chemical cleaning chamber, radiation cleaning chamber, an annealing chamber, a sputter cleaning chamber or a combination thereof. In a cleaning process, at least some of the material deposited on the susceptor is removed. It is not necessary to remove all the accumulated material. For example, a short, incomplete cleaning may be sufficient for a predetermined number of cleaning cycles, and a longer and/or more intensive cleaning may be performed intermittently. The suitable intensity of a cleaning process depends on the properties of the material accumulated on the susceptor and can be selected accordingly.

For example, oxygen plasma, nitrogen plasma, noble gas plasma (such as argon), hydrogen plasma or a combination thereof may be used to remove material from the susceptor surface. Variable other gases may be used in the treatment chamber in addition to the gases from which plasma is generated. Plasma may be used to generate reactive species from the additional gases to improve cleaning efficiency, for example. Such a treatment chamber may be termed a plasma cleaning chamber. A thermal cleaning may comprise heating the susceptor to a predetermined temperature. Depending on the material to be cleaned, at thermal cleaning may comprise selecting a suitable gas atmosphere. For example, an oxygen-containing, such as ozone-containing, atmosphere may be used to ash carbon-containing materials. In some embodiments, a thermal cleaning is performed in an oxidizing atmosphere. In some embodiments, a thermal cleaning is performed in a reducing atmosphere. A susceptor may be thermally cleaned by treating it at a temperature of at least 500° C. In some embodiments, a susceptor is cleaned by treating it at a temperature of at least 700° C. In some embodiments, a susceptor is cleaned by treating it at a temperature of at least 900° C. In some embodiments, a susceptor is cleaned by treating it at a temperature of at least 1,000° C. The appropriate cleaning temperature and the duration of thermal cleaning may be selected according to the material deposited on the susceptor that is to be removed. A treatment chamber configured and arranged to clean a susceptor thermally may be called a thermal cleaning chamber.

In some embodiments, a susceptor may be cleaned by using an etchant, i.e., a susceptor is cleaned by etching. In some embodiments, cleaning by etching is a wet etch cleaning. In some embodiments, cleaning by etching is a dry etch cleaning. There are numerous etch chemistries available to remove different accumulated materials. In some embodiments, halogen gas, such as fluorine, chlorine or bromine, is used as an etchant. In some embodiments, halogen-containing gas is used as an etchant. For example, gaseous hydrochloric acid may be used as an etchant. In some embodiments, a liquid hydrochloric acid solution is used as an etchant. In some embodiments, gaseous hydrofluoric acid may be used as an etchant. In some embodiments, a liquid hydrofluoric acid solution is used as an etchant. In some embodiments, an etchant comprising a halogen and carbon is used. In some embodiments, etchant is CF₄. In some embodiments, etchant is C₃F₈. A treatment chamber configured and arranged to clean a susceptor by etching may be called a etch cleaning chamber.

Although etching may be considered a chemical cleaning method in which the target material is dissolved by the etchant, in some embodiments, other chemical reactions may be employed in cleaning the susceptor. In some embodiments, a chemical reaction producing volatile end products is used. In some embodiments, a chemical reaction producing easily removeable solid end products is used. In some embodiments, radiation is used in cleaning the susceptor. In some embodiments, oxidizing chemistry may be used in cleaning a susceptor. For example, hydrogen peroxide may be used. A treatment chamber configured and arranged to clean a susceptor through a chemical reaction may be called a chemical cleaning chamber.

Radiation may be used to provide energy to remove accumulated material from the susceptor. In some embodiments, ionizing radiation is used in cleaning a susceptor. In some embodiments, non-ionizing radiation is used in cleaning a susceptor. In some embodiments, sonic cleaning may be used in cleaning a susceptor.

Heating the susceptor may be used to improve the cleaning efficiency of other cleaning methods. This may reduce the time needed for cleaning the susceptor. For example, a plasma clean may be performed in an elevated temperature. Cleaning by an etchant, or other chemical etching process may be performed in an elevated temperature. Elevated temperature may be selected according to the cleaning method and the accumulated material in question. An elevated temperature may be any temperature above ambient temperature. For example, an elevated temperature may be about 50° C., or about 100° C., or about 150° C., or about 200° C., or about 500° C. In some embodiments, an elevated temperature is from about 50° C. to about 800° C., or from about 50° C. to about 500° C., or from about 100° C. to about 800° C., or from about 200° C. to about 500° C. Different cleaning methods may be combined. The different cleaning methods may be performed simultaneously or consecutively. Additional steps, such as surface modification or chamber purging may be performed between different cleaning methods. For example, plasma and an etchant may be used together. In certain embodiments, susceptor cleaning process is similar to a substrate cleaning process applied in the deposition chamber. In such embodiments, substrates may be treated in a treatment chamber according to the current disclosure. However, in some embodiments, the treatment chamber is configured and arranged to treat susceptors. In some embodiments, the treatment chamber is configured and arranged to treat substrates and susceptors. In some embodiments, the treatment chamber is configured and arranged to treat only susceptors.

Some—especially sensitive—deposition processes may benefit from the susceptor surface having certain physical properties, such as charge, that may deteriorate during processing. In such embodiments, a susceptor may be conditioned before substrate processing to provide appropriate susceptor properties. In some embodiments, the treatment chamber is configured and arranged to condition a susceptor. In some embodiments, the conditioning comprises coating a susceptor. Coating a susceptor with appropriate material may improve the results, such as uniformity, of the deposition process. In some embodiments, a treatment chamber according to the current disclosure may be used to coat a susceptor. For example, wafer edge effects may be reduced if a susceptor surface comprises the same or similar material as the substrate being processed. In some embodiments, a susceptor may be coated with silicon carbide. In some embodiments, a susceptor may be coated with silicon nitride. In some embodiments, a susceptor may be coated with titanium nitride. In some embodiments, a susceptor is coated with the same material that is deposited on a substrate. In some embodiments, conditioning the susceptor comprises annealing. During annealing, a susceptor may be heat-treated in a predetermined temperature for a predetermined duration. An annealing temperature may be, for example, from about 800° C. to a about 1,200° C. Duration of annealing may be, for example, from about 0.5 seconds to about 50 seconds. Annealing may lead into alteration of material properties and/or composition. In some embodiments, low vapor pressure compounds may evaporate from a susceptor during annealing, which may contribute to the change in surface properties. Annealing may be combined with other conditioning methods, such as coating.

In some embodiments, the treatment chamber may be used for treating a substrate, as well as the susceptor. However, in some embodiments, a treatment chamber according to the current disclosure is a dedicated chamber for treating susceptors. For example, the conditions applied during cleaning a susceptor may differ from the conditions during deposition processes. Thus, in some embodiments, the components of a treatment chamber differ from those of the deposition stations.

A treatment chamber according to the current disclosure comprises the necessary components for performing the selected treatment in the treatment chamber. Thus, the treatment chamber may comprise, heaters, injection nozzles, exhausts, and other such features. In some embodiments, the treatment chamber is connected to a plasma generator.

In some embodiments, the treatment chamber is configured and arranged to treat the top surface of the susceptor. In some embodiments, the treatment chamber is configured and arranged to treat at least the top surface of the susceptor. In some embodiments, the treatment chamber is configured and arranged to treat only the top surface of the susceptor. In some embodiments, the treatment chamber is configured and arranged to treat the top surface and at least side surfaces of the susceptor. In some embodiments, the treatment chamber is configured and arranged to treat the bottom surface of the susceptor. In some embodiments, the treatment chamber is configured and arranged to treat at least the bottom surface of the susceptor. By a top surface is herein meant a surface of a susceptor on which a substrate will rest during a deposition process. By a bottom surface is herein meant a surface of a susceptor which is opposite to the top surface.

In some embodiments, the treatment chamber comprises a tray for the susceptor. The tray may be used to protect those surfaces of the susceptor that are used to connect the susceptor with the susceptor stand of a susceptor moving arrangement in the deposition chamber. The tray may comprise connections, such as electrical connections, similar to those of a susceptor stand. The connections may be used to heat the susceptor.

### Transfer System

The vapor deposition assembly according to the current disclosure comprises a transfer system configured and arranged to move a susceptor between a deposition chamber and a treatment chamber. The transfer system may comprise an arm with susceptor holding means. For example, a robot arm may comprise a fork that fits a susceptor. A susceptor and a susceptor holding means, such as a fork or a grabber, may be shaped complementarily. A complementary shape of a susceptor and a susceptor holding means may allow securing a susceptor to the susceptor holding means when the susceptor is transferred between a deposition chamber and a treatment chamber. A transfer system may move susceptors from a deposition chamber to a treatment chamber. A transfer system may move susceptors from a treatment chamber to a deposition chamber. The transfer system may comprise separate components for moving a susceptor from a deposition chamber to a treatment chamber and from a treatment chamber to a deposition chamber.

In addition to transferring susceptors between a deposition chamber and a treatment chamber, the transfer system may be configured and arranged to move substrates, such as silicon wafers. The transfer system may be adjustable so that it can be used to move susceptors and substrates. The substrates may be moved from one deposition chamber to another by the transfer system. The substrates may be moved from a deposition chamber to a loadlock by the transfer system. In some embodiments, a substrate may be moved on the susceptor when the susceptor is moved by the transfer system. In some embodiments, the transfer system is configured and arranged to move only susceptors. In such embodiments, the vapor deposition assembly according to the current disclosure comprises additional means for moving substrates. In some embodiments, the transfer system may switch between a susceptor movement mode and a substrate transfer mode. Thus, in some embodiments, the deposition assembly comprises a substrate-handling system, and the substrate-handling system is configured and arranged to be used as the susceptor transfer system. However, in some embodiments, the vapor deposition assembly comprises a separate substrate-handling system and a separate transfer system.

In some embodiments, the transfer system moves a susceptor in and out of a treatment chamber, and the susceptor is not moved inside the treatment chamber. In some embodiments, the vapor deposition assembly comprises only one transfer system, and the transfer system is configured and arranged to move susceptors inside a treatment chamber. However, in some embodiments, the deposition assembly comprises a second transfer system configured and arranged to move a susceptor inside the treatment chamber. For example, in embodiments in which multiple susceptors may be treated simultaneously, it may be advantageous to have more than one position for susceptors inside the treatment chamber.

In some embodiments, the assembly comprises more susceptors than deposition stations. Such embodiments may allow the continuous or substantially continuous operation of all the deposition stations. One or more susceptors may be cleaned or otherwise treated in a treatment chamber while all positions available for susceptors in a deposition chamber remain occupied and in use. In some embodiments, the vapor deposition assembly comprises at least one more susceptor than there are deposition stations in the deposition assembly. In some embodiments, the vapor deposition assembly comprises at least two more susceptors than there are deposition stations in the deposition assembly. In some embodiments, the vapor deposition assembly comprises at least three more susceptors than there are deposition stations in the deposition assembly. In some embodiments, the vapor deposition assembly comprises at least four more susceptors than there are deposition stations in the deposition assembly. In some embodiments, the vapor deposition assembly comprises at least five more susceptors than there are deposition stations in the deposition assembly. In some embodiments, the vapor deposition assembly comprises, at least six more susceptors than there are deposition stations in the deposition assembly. In some embodiments, the vapor deposition assembly comprises at least seven more susceptors than there are deposition stations in the deposition assembly. The number of susceptors in excess of the deposition stations depends on the configuration of each vapor deposition assembly. This again may depend on the features of the processes, such as their duration, run in individual deposition chambers and/or deposition stations.

For example, a vapor deposition assembly according to the current disclosure may comprise two deposition chambers, each comprising four deposition stations. The vapor deposition assembly may comprise ten susceptors. In such an embodiment, each deposition chamber may comprise one more susceptor than there are deposition stations in that deposition chamber. Thus, for each deposition chamber, one susceptor may be treated in a treatment chamber, while the other susceptors continue to be used in the deposition processes in the deposition chambers. Such and embodiment may comprise one or two treatment chambers. Alternatively, the vapor deposition assembly may comprise twelve or more susceptors, increasing the number of susceptors that can be treated simultaneously without reducing the number of deposition stations being used in the deposition chambers. Similarly, a vapor deposition assembly may comprise three or more, four or more, or five or more deposition chambers, each of the deposition chambers comprising at least two deposition stations. The number of deposition stations in different deposition chambers can be the same or different. In addition to deposition stations, the deposition chambers may comprise additional positions to hold susceptors. For example, substrates may be loaded and/or unloaded on/from susceptors in dedicated positions. In such embodiments, the number of susceptors in the deposition assembly may be correspondingly larger.

In some embodiments, a deposition assembly comprising at least two deposition chambers, each comprising at least two deposition stations, comprises one more susceptor than there are deposition stations in the deposition assembly. Such embodiments may be used for processes in which the interval between susceptor treatment is relatively long and/or in which the susceptor treatment is short.

In embodiments comprising more susceptors than deposition stations in a deposition assembly, it may be advantageous to hold one or more treated susceptors ready for use in a dedicated position. In some embodiments, it may be advantageous, to hold one or more susceptors ready for treatment in a dedicated position. Such position for holding susceptors is called a susceptor staging station in the current disclosure. In some embodiments, the assembly further comprises a susceptor staging station for holding a treated susceptor. In some embodiments, the assembly further comprises a susceptor staging station for holding a susceptor that will be treated. In some embodiments, the susceptor staging station is positioned in the deposition chamber. In some embodiments, the susceptor staging station is positioned in the treatment chamber. In some embodiments, there may be more than one, such as two, three or four, susceptor staging stations for each deposition chamber. The susceptor staging stations may be positioned in any suitable location in the deposition assembly, such as in a deposition chamber, in a treatment apparatus or in both.

In some embodiments, the treatment chamber is configured and arranged to receive susceptors from at least two deposition chambers. A treatment chamber is thus connected to at least two deposition chambers in a way that allows moving susceptors from each deposition chamber to the treatment chamber. The treatment chamber may comprise one transfer system serving all connected deposition chambers. Alternatively, each deposition chamber may comprise its own transfer system for moving susceptors between the treatment chamber and the deposition chamber in question.

A vapor deposition assembly according to the current disclosure may thus comprise a treatment chamber shared by two or more deposition chambers. In some embodiments, a treatment chamber is configured and arranged to receive susceptors from two deposition chambers. In some embodiments, a treatment chamber is configured and arranged to receive susceptors from three deposition chambers. In some embodiments, a treatment chamber is configured and arranged to receive susceptors from four deposition chambers. The number of deposition chambers sharing a treatment chamber depends on the configuration of a deposition assembly in question. A shared treatment chamber may comprise a loading port for each deposition chamber it is connected to. In some embodiments, the atmosphere in the treatment chamber is separable from the atmospheres of the deposition chamber(s). In some embodiments, the treatment chamber is configured to have an atmospheric connection to only one deposition chamber at a time. This may avoid mixing of atmospheres in different deposition chambers. In embodiments comprising a shared transfer chamber, either the treatment chamber or the deposition chambers may comprise a susceptor staging station.

In one aspect, a treatment apparatus for treating susceptors of a vapor deposition assembly is disclosed. A treatment apparatus according to the current disclosure may be an integral component of a deposition assembly. However, In some embodiments, a treatment apparatus according to the current disclosure may be a separate unit that can be attachable to a vapor deposition assembly.

The treatment apparatus according to the current disclosure comprises a housing, a susceptor holder configured an arranged to hold a susceptor to be treated and a treatment arrangement configured and arranged to treat a susceptor. The treatment apparatus may comprise a separate treatment chamber for holding a susceptor during a treatment. The treatment apparatus is configured and arranged to receive a susceptor from at least two deposition chambers. The treatment arrangement according to the current disclosure comprises the components used in treating a susceptor, and their construction depends on the kind of treatment the treatment apparatus is configured to perform. For example, the treatment apparatus may be a thermal cleaning apparatus, and it may comprise a heater, thermostat and an optional gas inlet for regulating the atmosphere in the treatment chamber of the treatment apparatus. The treatment apparatus may further comprise an exhaust for removing gases and volatile compounds from the treatment chamber of the treatment apparatus.

The treatment apparatus may further comprise one or more ports for moving susceptors in and out of the treatment chamber. In some embodiments, the treatment apparatus comprises two ports for moving susceptors between the treatment apparatus and the deposition chamber. In some embodiments, the treatment apparatus comprises two ports for moving susceptors between the treatment apparatus and the deposition chamber. Also a treatment chamber according to the current disclosure may comprise ports for connecting a treatment chamber to a deposition chamber.

In another aspect, a method of cleaning a susceptor is disclosed. A method of cleaning a substrate comprises removing a susceptor from a susceptor moving arrangement in a vapor deposition chamber comprising at least two deposition stations, inserting the susceptor in a susceptor cleaning chamber connected to the vapor deposition chamber, and cleaning the susceptor.

In some embodiments, cleaning comprises providing a plasma in the susceptor cleaning chamber and/or heating the susceptor cleaning chamber.

In some embodiments, cleaning comprises providing an etchant in the susceptor cleaning chamber. In some embodiments, cleaning comprises cleaning nitride material from the susceptor. In some embodiments, the material cleaned form the susceptor is titanium nitride. In some embodiments, the material cleaned form the susceptor is silicon nitride. In some embodiments, the material cleaned from the susceptor is elemental metal. For example, the elemental metal may be a transition metal, such as molybdenum, tungsten, chromium, rhenium, cobalt, nickel or copper. In some embodiments, the material cleaned from the susceptor is an oxide, such as a metal or metalloid oxide. For example, the material cleaned from the susceptor may be silicon oxide or germanium oxide. In some embodiments, the material cleaned from the susceptor is a transition metal oxide. In some embodiments, the transition metal oxide is aluminum oxide, titanium oxide, hafnium oxide or a copper oxide. In some embodiments, the material cleaned from the susceptor is a carbide, such as a metal or metalloid carbide. For example, the carbide may be a silicon carbide. By a metalloid is herein meant elements boron, silicon, germanium, arsenic, antimony and tellurium.

In one aspect, a method of removing nitride material from a susceptor is disclosed. The method of removing nitride material from a substrate comprises removing a susceptor from a susceptor moving arrangement in a vapor deposition chamber comprising at least two deposition stations, inserting the susceptor in a susceptor cleaning chamber connected to the vapor deposition chamber, and removing nitride material from the susceptor. Nitride material, such as silicon nitride or titanium nitride, may have accumulated on a susceptor during a vapor deposition process, for example, during the manufacture of an electronic device.

In one aspect, a method of removing silicon nitride from a susceptor is disclosed. The method of removing silicon nitride from a substrate comprises removing a susceptor from a susceptor moving arrangement in a vapor deposition chamber comprising at least two deposition stations, inserting the susceptor in a susceptor cleaning chamber connected to the vapor deposition chamber, and removing silicon nitride from the susceptor.

In one aspect, a method of removing titanium nitride from a susceptor is disclosed. The method of removing titanium nitride from a substrate comprises removing a susceptor from a susceptor moving arrangement in a vapor deposition chamber comprising at least two deposition stations, inserting the susceptor in a susceptor cleaning chamber connected to the vapor deposition chamber, and removing titanium nitride from the susceptor.

The disclosure is further explained by the following exemplary embodiments depicted in the drawings. The illustrations presented herein are not meant to be actual views of any particular deposition assembly or a tool, but are merely schematic representations to describe embodiments of the current disclosure. The deposition assemblies and their components depicted in the drawings may contain additional elements and details, which are omitted for clarity. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

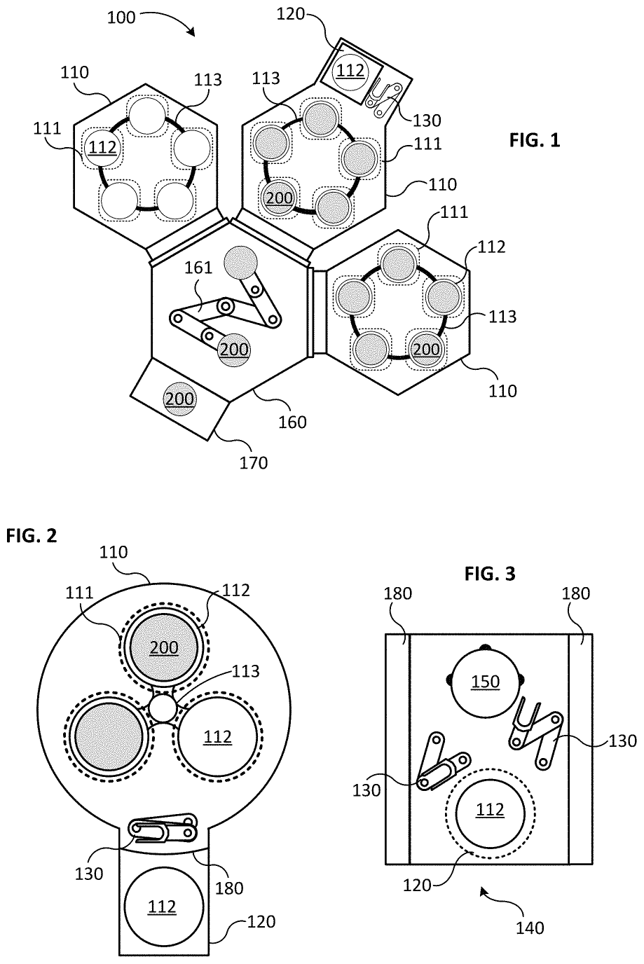

FIG. 1 is a schematic overview of a deposition assembly according to the current disclosure as a top view. The embodiment of FIG. 1 displays a vapor deposition assembly 100 comprising three deposition chambers 110. The deposition chambers 110 are multi-station chambers. Each deposition chamber 110 comprises at least two susceptors 112 mounted on a susceptor moving arrangement 113. The susceptor moving arrangement 113 is schematically represented by a circle, which could, for example, be a rotating rail in the deposition chamber 110. However, a susceptor moving arrangement 113, can be designed in various ways, and the current disclosure is not limited to any specific type or design of a susceptor moving arrangement 113. In the embodiment of FIG. 1, each deposition chamber comprises the same number of deposition stations 111, i.e. five. However, the design, including the number of deposition stations 111, may be independently selected for each deposition chamber 110.

In two of the deposition chambers 110, substrates 200 are displayed on the susceptors, whereas in one deposition chamber 110, substrates 200 are omitted for illustration purposes. As FIG. 1 depicts a vapor deposition assembly 100 as a top view, all chamber structures above susceptors 112 have been omitted. However, deposition stations 111 are shown with a dashed line around the susceptors 112. In FIG. 1, each deposition chamber comprises five deposition stations 111, one for each susceptor 112 in the susceptor moving arrangement 113. It is possible, however, to design a deposition chamber 110 that contains one less deposition station than there are positions for susceptors in a susceptor moving arrangement 113. This additional position may be used for loading and/or unloading susceptors 112 to the susceptor moving arrangement 113 without affecting the processing of substrates 200 in the deposition stations 111.

In the schematic presentation of FIG. 1, all the susceptors 112 are positioned at deposition stations 111. As the susceptors move from one deposition station to another, they rotate on the susceptor moving arrangement 113 in a circular pattern about a rotational axis. The rotational axis is in between the susceptors and, the rotational axis extends vertically (i.e. towards the viewing direction) from the plane of the substrates. Thus, in this embodiment, all the susceptors 112 may move simultaneously.

In the embodiment of FIG. 1, the center-most deposition chamber 110 of the three deposition chambers, comprises a treatment chamber 120. A susceptor 112 is illustrated inside the treatment chamber 120, and a transfer system 130 is depicted next to the treatment chamber 120. Although the transfer system 130 is depicted to comprise a single robot arm, in some embodiments there may be two or more robot arms in a transfer system 130. In some embodiments, a transfer system 130 may comprise other means of moving a susceptor between a deposition chamber 110 and a treatment chamber 120 than robot arms.

In addition to the deposition chambers 110, a vapor deposition assembly 100 comprises a loadlock 170 for loading substrates 200 into the vapor deposition assembly 100, and a transfer chamber 160, through which substrates 200 are moved to and from deposition chambers 110 by a transfer chamber robot arm 161 or by an analogous system. There may be gas seals, ports or the like, between each of these compartments (i.e. loadlock 170, transfer chamber 160 and deposition chamber 110) to separate processing atmospheres in the compartments from each other, and to avoid contaminating substrates 200. A substrate 200 according to the current disclosure may be a semiconductor substrate, such as a silicon wafer. A substrate may already comprise material deposited on it during earlier processing, and/or partially fabricated semiconductor devices.

In a method according to the current disclosure, a susceptor targeted for treatment in a treatment chamber 120 is caught by a transfer system 130 and moved to the treatment chamber 120. The susceptor 112 may then be treated in the treatment chamber 120 and returned to the deposition chamber 110 by the transfer system 130. During one of the susceptors 112 is being moved, treated, or waiting to be treated, the deposition processed in the deposition chamber 110 may continue at least for the other susceptors. The position in the susceptor moving arrangement 113 for the susceptor 112 being treated may remain vacant, or the position may be filled with another susceptor 112. A substrate 200 may be positioned on the replacement susceptor 112, so that all positions of susceptors 112 and deposition stations 111 may continue to be used while one of the susceptors 112 is being treated.

A susceptor 112 may be targeted for treatment in a treatment chamber by various means. For example, a susceptor 112 may be targeted for treatment, such as cleaning, after a pre-determined number of deposition cycles. The accumulation of material on the susceptor 112 may be predicted based on the process or processes that are run in a given deposition chamber 110 or in a vapor deposition assembly 100, and the interval between treatments determined based on that information. In some embodiments, the deposition assembly 100 may comprise means of detecting susceptor 112 condition by, for example using detectors and computer-implemented means, and a susceptor 112 may be targeted for treatment when a pre-determined threshold value indicating susceptor 112 condition is reached.

FIG. 2 depicts an embodiment of a deposition chamber 110 and a treatment chamber 120 according to the current disclosure as a top view. All other components of a deposition assembly have been omitted for simplicity. The deposition chamber depicted in FIG. 2 may, however, be one of several deposition chambers on a vapor deposition assembly. The cross-sectional profile of the deposition chamber 110 in this embodiment, is circular. However, the shape of the reaction chamber 110 may be a design choice and may vary. The deposition chamber 110 comprises three deposition stations 111 and three susceptors 112 attached to a susceptor moving arrangement 113. The susceptor moving arrangement 113 of the embodiment in FIG. 2 comprises three arms extending from a central axis, each arm holding a susceptor. Although the number of deposition stations, and corresponding arms is three in this embodiment, the number may vary as described for the embodiment of FIG. 1. The deposition stations 111 are again illustrated as dashed lines around the susceptors.

FIG. 2 presents a treatment chamber 120 connected to the deposition chamber 110, and a transfer system 130 for moving susceptors between the susceptor moving arrangement 113 and the treatment chamber 120. The transfer system 130 is positioned so that, in an idle state, it does not interfere with the movement of the susceptors by the susceptor moving arrangement 113. When a susceptor 112 is targeted for treatment in the treatment chamber 120, susceptor moving arrangement 113 will position the susceptor at a suitable distance from the transfer system 130 for being picked up. In some embodiments, the position from which a susceptor 112 is picked up by a transfer system 130 is a different position than a deposition station 111. In some embodiments, the position from which a susceptor 112 is picked up by a transfer system 130 is the same position as a deposition station 111. When a susceptor is positioned suitably, a transfer system 130, illustrated by a robot arm comprising a susceptor holding means (fork in this embodiment), will pick the susceptor from the susceptor moving arrangement 113 and move it to a treatment chamber 120.

In FIG. 2, a port or a gate 180 is schematically drawn between the deposition chamber 110 and the treatment chamber 120. In such embodiments, susceptors 112 may be treated in a space directly on the other side of the port/gate 180. However, in some embodiments, a treatment chamber 120 may be incorporated into a larger treatment apparatus comprising more than one compartment. This may be the case, for example, if susceptors are stored in a treatment chamber 120, and it is not desired that they become repeatedly exposed to the treatment performed in the treatment chamber 120. Further, in embodiments in which a treatment chamber 120 is connected to more than one deposition chamber 110, it may be desired to separate the susceptors 112 coming from different deposition chambers 110 before and/or after treatment to avoid any contamination between deposition chambers 110, as different deposition processes may be run in them.

FIG. 3 presents an embodiment of a treatment apparatus 140 according to the current disclosure as a schematic top view. In the embodiment of FIG. 3, the treatment chamber 120 is not directly connected to a deposition chamber 110. The treatment chamber 120 is positioned inside a treatment apparatus 140. The treatment apparatus 140 is connected to two deposition chambers (not shown) through ports/gates 180. Although in this embodiment of a treatment chamber 120 and a treatment apparatus 140, the treatment chamber 120 is in contact with, and susceptors are received from, two deposition chambers, in some embodiments, a treatment apparatus 140 is in contact with one deposition chamber. In some embodiments, a treatment apparatus 140 is in contact with three deposition chambers. In some embodiments, a treatment apparatus 140 is in contact with four deposition chambers. In some embodiments, a treatment apparatus 140 is in contact with at least two deposition chambers. Thus, in such embodiments, a treatment chamber 120 is configured and arranged to receive susceptors 112 from at least two deposition chambers.

The ports/gates 180 may be regulated in a manner that avoids the mixing of the gases between the deposition chambers. Various alternatives are known in the art for designing such gates. The gates—as the rest of the equipment in the vapor deposition apparatus—may be controlled by a computer system.

The treatment apparatus 140 of FIG. 3 comprises two transfer systems 130 for moving susceptors from the deposition chambers into the treatment chamber 120. In some embodiments, a treatment apparatus 140 comprises one transfer system 130. In some embodiments, a treatment apparatus 140 comprises three transfer systems 130. In some embodiments, a treatment apparatus 140 comprises two or more transfer systems 130. In some embodiments, all transfer systems 130 are positioned in a treatment apparatus 140. In some embodiments, all transfer systems 130 are positioned in deposition chambers. In some embodiments, a treatment apparatus 140 comprises at least one transfer systems 130 and a deposition chamber comprises at least one transfer system 130. Thus, the number and positioning of transfer systems 130 may be selected suitably for each vapor deposition assembly. Each transfer system 130 may be used to move susceptors between the treatment apparatus 140 and one deposition chamber 110. Alternatively, one transfer system 130 may be used to mover susceptors from more than one deposition chamber 110 to the treatment chamber 120 or to a treatment apparatus 140.

In addition to robot arms, a transfer system 130 may comprise a susceptor staging station 150 for temporarily holding a susceptor 112. For example, a susceptor 112 may be removed from a susceptor moving arrangement and placed in a susceptor staging station 150 to wait for being moved into a treatment chamber 120. Similarly, a treated susceptor 112 may be placed in a susceptor staging station 150 to wait for being moved into a deposition chamber. In some embodiments, a deposition chamber comprises a susceptor staging station 150. A possibility to hold susceptors both in the treatment apparatus and in the deposition chamber when the susceptors 112 are not in use or not being treated may offer advantages in some embodiments. For example, it may be possible to open a port/gate 180 only during limited times, and the possibility to hold susceptors ready for treatment or use, as the case may be, may improve efficiency of the deposition assembly and allow for increased throughput. In some embodiments, a vapor deposition assembly according to the current disclosure comprises separate susceptor staging stations 150 for holding treated and untreated susceptors 112. The same transfer robots that move susceptors from a deposition chamber to the treatment chamber 120 may be used for moving susceptors to and from a susceptor staging station 150. Alternatively, susceptor staging station 150 may have a dedicated robot.

In the embodiment of FIG. 3, a treatment chamber 120 (dashed circle) is a separate compartment inside the treatment apparatus 140. The treatment chamber 120 may be operated similarly to the deposition stations 111 in the deposition chamber 110, with the necessary adjustments to account for the difference in purpose. The exact design and components of the treatment chamber 120 depend on the treatment(s) performed in the treatment chamber 120.

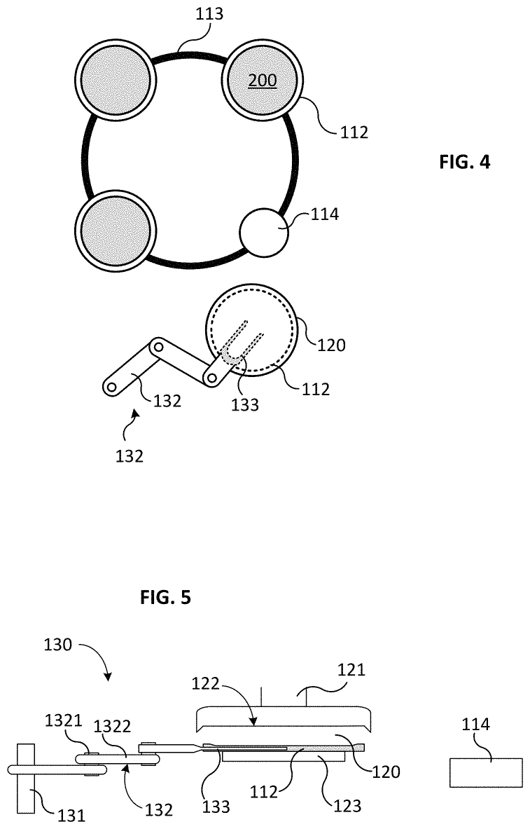

FIG. 4 depicts an embodiment of a deposition chamber and a treatment chamber according to the current disclosure as a top view. In this figure, most deposition chamber structures, including deposition stations are omitted for clarity. FIG. 4 illustrates how a susceptor 112 has been removed from a susceptor moving arrangement 113 by a transfer system arm 132, and inserted in a treatment chamber 120. In this embodiment, the treatment chamber 120 is located in the deposition chamber, close to the susceptor moving arrangement 113 and the deposition stations (not shown).

In this figure, the susceptor stand 114 for the susceptor 112 being treated is visible. All details of the susceptor stand 114 have been omitted for clarity. The susceptor 112 to be cleaned in the treatment chamber 120 is indicated with dashed line, as in this view, it is located under a treatment chamber 120 structure (“lid”, see FIG. 5). Similarly, in reality, the susceptor holding means 133 (fork in this embodiment) of a transfer robot is not visible and its outline is therefore indicated with a dashed line.

FIG. 5 presents the embodiment of FIG. 4 as a schematic side view, focusing on the features of the treatment chamber 120 and transfer system 130. The susceptor moving arrangement is represented in the figure by the susceptor stand 114 from which the susceptors 112 being treated has been removed. It is appreciated that a susceptor stand 114 may contain various structural features relating to careful positioning and firm holding of a susceptor 112 that have been omitted from the present illustration.

The components of a transfer system 130 visible in FIG. 5 are the body 131, which connects the arm 132 to the base of the deposition chamber, and to control means controlling the transfer system 130. The arm 132 is hinged, and optionally equipped with actuators or other means to move sections 1322 of the arm relative to the hinges 1321. A susceptor holding means 133, again illustrated by a fork, is shown at the end of the arm 132 inserting the susceptor 112 into a treatment chamber 120. The susceptor holding means 133 may be removed for the duration of the treatment. In some embodiments, however, the susceptor holding means 133 may remain attached to the susceptor during the treatment in the treatment chamber 120.

The susceptor holding means 133 may be moveable vertically. Vertical movement may be used, for example, in embodiments in which a susceptor staging station containing multiple rack positions for susceptors is used. Also, in embodiments in which the same transfer system 130 is used for both susceptors and substrates may have advantage of vertically moveable susceptor holding means (which in such a case, would also serve as a substrate holding means). In such embodiments, the height of the susceptor holding means 133 may be selected according to the component to be moved by the transfer system (i.e. substrate or susceptor).

In the embodiment of FIG. 5, the treatment chamber 120 comprises a susceptor tray 123 and an injector 122 providing the treatment gases or plasma into the treatment chamber 120. Gases and/or plasma used in the treatment chamber 120 are provided through a gas line 121. A gas line may comprise several channels (not shown), conduits or tubes for different gases. In this embodiment, the injector 122 serves as a lid to the treatment chamber. The treatment chamber 120 is closed by bringing the injector 122 and the susceptor 112 together. Thus, the susceptor 112 forms a part of the treatment chamber 120 enclosure. In some embodiments, the susceptor tray 123 and the injector 122 are used to close the treatment chamber 120 while the susceptor rests on the susceptor tray 123. The susceptor tray may be larger than indicated in FIG. 5, so that its edge extends outside the susceptor 112 edge. In some embodiments, the injector 122 is a separate structure from the treatment chamber lid. The design of the injector 122 may depend on the type of treatment performed in the treatment chamber 120. A treatment chamber may comprise more than one injector 122.

In some embodiments, the treatment chamber 120 may be closed by lowering the injector 122 or other treatment chamber 120 structures to meet the susceptor 112 or the susceptor tray 123. In some embodiments, the treatment chamber 120 may be closed by raising the susceptor tray 123 for the susceptor or the susceptor tray 123 to meet the injector 122 or other structures of the treatment chamber 120.

Gases, including any material removed from a susceptor surface are removed from a treatment chamber through one or more exhausts (not shown). The exhausts may be positioned in various positions. In some embodiments, exhaust is positioned in the injector 122 which may have inlet openings and exhaust openings. The inlet openings and exhaust openings may be separate openings. In some embodiments, exhaust may be located in the susceptor tray.

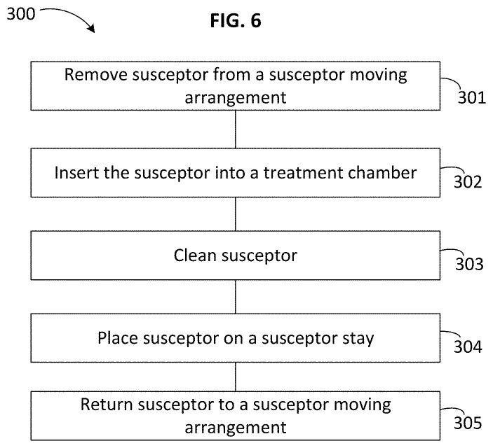

FIG. 6 is a flow diagram presenting an embodiment of a method 300 according to the current disclosure. In the method, a susceptor is removed from a susceptor moving arrangement at phase 301. The susceptor is then inserted into a treatment chamber at phase 302. In some embodiments, the susceptor may be held temporarily in a susceptor staging station before inserting into a treatment chamber. At phase 303, the susceptor is cleaned. In some embodiments, nitride material, such a titanium nitride or silicon nitride is cleaned from the susceptor. The current disclosure is not limited to these materials. Instead, various materials, such as oxides, carbides, sulfides and elemental metals may be removed from a susceptor during cleaning. Phase 304 presented in FIG. 6, namely placing the susceptor on a susceptor tray, is optional. In some embodiments, a susceptor is placed on a susceptor tray after treatment. In some embodiments, a susceptor is not placed on a susceptor tray after treatment. In some embodiments, a susceptor is placed on a susceptor stand of a susceptor moving arrangement directly after treatment. In phase 305, the susceptor is returned to a susceptor moving arrangement. In some embodiments, the susceptor is returned to the same susceptor stand from which it was removed at phase 301. In some embodiments, the susceptor is returned to a different susceptor stand from which it was removed at phase 301. In some embodiments, the susceptor is returned to the same susceptor moving arrangement from which it was removed at phase 301. In such embodiments, the susceptor stand may be the same or a different one. In some embodiments, the susceptor is returned to a different susceptor moving arrangement from which it was removed at phase 301.

An individual susceptor may be subjected to a cleaning method according to the current disclosure multiple times. In some embodiments, a vapor deposition assembly according to the current disclosure has means to detect the need for a susceptor to be cleaned. For example, properties of a substrate surface may be monitored. In some embodiments, the need for a susceptor to be cleaned may be calculated in advance based on the deposition processes performed in the deposition chamber.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A vapor deposition assembly for depositing material on a substrate, the vapor deposition assembly comprising
a deposition chamber comprising
at least two deposition stations for depositing a material on a substrate;
a plurality of susceptors each configured and arranged to hold a substrate;
a susceptor moving arrangement configured and arranged to detachably hold a susceptor and to move said susceptor between deposition stations
a treatment chamber constructed and arranged to receive and treat a susceptor from the deposition chamber; and
a transfer system configured and arranged to move the susceptor between the deposition chamber and the treatment chamber.

2. The deposition assembly of claim 1, wherein the deposition assembly comprises a second transfer system configured and arranged to move a susceptor inside the treatment chamber.

3. The deposition assembly of claim 1, wherein the susceptor moving arrangement is configured and arranged to move all the susceptors simultaneously.

4. The deposition assembly of claim 3, wherein the susceptor moving arrangement rotates the susceptors in a circular manner about a rotational axis.

5. The deposition assembly of claim 1, wherein the assembly further comprises a susceptor staging station for holding a treated susceptor.

6. The deposition assembly of claim 5, wherein the susceptor staging station is positioned in the deposition chamber.

7. The deposition assembly of claim 1, wherein the assembly comprises more susceptors than deposition stations.

8. The deposition assembly of claim 1, wherein the treatment chamber is a cleaning chamber.

9. The deposition assembly of claim 8, wherein the cleaning chamber is a plasma cleaning chamber, a thermal cleaning chamber, an etch cleaning chamber, a chemical cleaning chamber, radiation cleaning chamber, an annealing chamber, a sputter cleaning chamber or a combination thereof.

10. The deposition assembly of claim 1, wherein the treatment chamber is configured and arranged to treat a susceptor.

11. The deposition assembly of claim 1, wherein the treatment chamber is configured and arranged to treat a substrate and a susceptor.

12. The deposition assembly of claim 1, wherein the treatment chamber is configured and arranged to condition a susceptor.

13. The deposition assembly of claim 12, wherein the conditioning comprises coating a susceptor.

14. The deposition assembly of claim 12, wherein the conditioning comprises annealing a susceptor.

15. The deposition assembly of claim 1, wherein the deposition assembly comprises a substrate-handling system, and the substrate-handling system is configured and arranged to be used as the susceptor transfer system.

16. The deposition assembly of claim 1, wherein the treatment chamber is configured and arranged to receive susceptors from at least two deposition chambers.

17. A treatment apparatus for treating a susceptor of a vapor deposition assembly comprising
a housing;
a susceptor holder configured an arranged to hold a susceptor to be treated;
a treatment apparatus configured and arranged to treat a susceptor;
wherein the susceptor treatment apparatus is configured and arranged to receive a susceptor from at least two deposition chambers.

18. The treatment apparatus of claim 17, wherein the treatment apparatus comprises transfer system for moving susceptor between the susceptor holder and a deposition chamber.

19. The treatment apparatus of claim 17, wherein the treatment apparatus comprises a susceptor staging station for storing susceptors.

20. A method of cleaning a substrate comprising removing a susceptor from a susceptor moving arrangement in a vapor deposition chamber comprising at least two deposition stations;
inserting the susceptor in a susceptor cleaning chamber connected to the vapor deposition chamber; and
cleaning the susceptor.

21. The method of claim 20, wherein cleaning comprises providing a plasma in the susceptor cleaning chamber and/or heating the susceptor cleaning chamber.

22. The method of claim 20, wherein cleaning comprises providing an etchant in the susceptor cleaning chamber.

23. The method of claim 20, wherein cleaning comprises cleaning nitride material from the susceptor.
